(19) United States
(12) Patent Application Publication
(10) Pub. No.: US 2012/0192927 A1
(43) Pub. Date: Aug. 2, 2012

(54) Photovoltaic Module with Integral Junction

(76) Inventors: George D. Peterson, Mt. Top, PA (US); Robert Bennett, Spotsylvania, VA (US); Troy Sacra, Partlow, VA (US)

(21) Appl. No.: 13/220,085

(22) Filed: Aug. 29, 2011

Related U.S. Application Data
(60) Provisional application No. 61/402,233, filed on Aug. 27, 2010.

(51) Int. Cl. H01L 31/048; H01L 31/05; H01L 31/0203

(52) U.S. Cl. 136/251; 136/259

(57) ABSTRACT

A photovoltaic module with integral junction includes a photovoltaic assembly having at least one photovoltaic cell. A by-pass diode is located at the junction between a positive output cable and a negative output cable of the photovoltaic module. The diode selectively electrically joins the positive output cable with the negative output cable, thereby by-passing the photovoltaic cell assembly. Encapsulating material completely surrounds the photovoltaic assembly and the by-pass diode within a single integral unit. In one advantageous form, the encapsulating material is a polymer, such as ethylene vinyl acetate polymer.

### CROSS REFERENCE TO RELATED APPLICATIONS

This application claims the benefit of U.S. provisional application No. 61/402,233, filed Aug. 27, 2010 herein incorporated by reference.

### FIELD OF THE INVENTION

The present invention relates to a photovoltaic module and, in particular a photovoltaic module having an integral junction.

### BACKGROUND OF THE INVENTION

Electrical solar energy production is conventionally produced using photovoltaic cells. Typically, the photovoltaic cells are arranged in an assembly which includes several photovoltaic cells. The assembly of photovoltaic cells are incorporated into a photovoltaic module. Then, the modules, each comprising a number of photovoltaic cells, are joined together to form an array of photovoltaic modules. The photovoltaic modules typically each have a junction within the module between a positive conductor wire and a negative conductor wire which are both connected to the photovoltaic cell assembly, i.e. the one or more individual photovoltaic cells which comprise the photovoltaic module. The conducting wires are used for allowing to current to flow through the photovoltaic module from one module to a next module with the photovoltaic array.

The photovoltaic modules require a means for interconnecting the modules to one another to form an array of photovoltaic modules and to allow for installation and replacement of individuals modules within the array. Modules generate a voltage drop across the photovoltaic cell assembly. In order to accommodate the voltage drop across the photovoltaic cell assembly between the positive side and the negative side, i.e. between a positive output cable and a negative output cable, a by-pass diode is used for allowing current to flow through conventional photovoltaic modules.

Conventional photovoltaic modules have the diode located in a junction box outside the photovoltaic module. Referring to one prior art photovoltaic module with by-pass diode, FIG. 6 depicts a typical external junction box which is located outside of the photovoltaic module. Positive and negative wires exit the photovoltaic module and lead into the external junction box. The positive output wires and negative output wires are connected to teach other and a by-pass diode is located at an intersection between the positive and negative output cables. Upon failure of the photovoltaic module, current by-passes the photovoltaic module and proceeds between the positive output and the negative output. One example of such a junction box can be found in U.S. Patent Application Publication No. 2011/0114158.

Unfortunately, prior junctions boxes have limitations in that they are relatively large (e.g., thick) and susceptible to moisture leakage. The relatively large size of conventional junction boxes make their use inappropriate for integration in some integrated photovoltaic applications, such as solar shingles and slates. In addition, current junction boxes are typically complex plastic junction boxes requiring sealing and a field assembly. Improper assembly, condensation and environmental exposure may cause these junction boxes to leak or short circuit the output. Further, difficulty in accessing junction boxes after installation on a surface, such as a roof, for service and repair is complicated due to current junction box designs.

What is needed in the art is a new and improved junction for a photovoltaic module which overcomes the problems with current junction box designs and which provides features and advantages not found in current designs.

### SUMMARY OF THE INVENTION

The present invention relates to a photovoltaic module with integral junction. The photovoltaic module includes a photovoltaic assembly comprising at least one photovoltaic cell. The photovoltaic assembly has a by-pass diode at a junction between a positive output wire and a negative output wire to selectively electrically join a positive side of the photovoltaic module with a negative side of the photovoltaic module, thus by-passing the photovoltaic assembly to thereby allow current to pass through the photovoltaic module without going through the photovoltaic assembly which comprises the photovoltaic cells. Encapsulating material completely surrounds the photovoltaic assembly and the by-pass diode within a single integral unit. Positive and negative output cables extend from inside the integral unit to the outside of the integral unit which allow the photovoltaic module to be connected to other modules to thereby form a photovoltaic array of modules. Optionally, the photovoltaic module is laminated in a suitable material to thereby completely seal the photovoltaic module.

In one specific further embodiment, the encapsulating material comprises a non-conductive material in the form of layers above, below and, optionally, around the by-pass diode and photovoltaic assembly, thereby completely encapsulating the photovoltaic cell assembly and by-pass diode in the integral unit.

The present invention, in one form thereof, relates to a photovoltaic module with integral junction. The photovoltaic module includes a photovoltaic assembly comprising at least one photovoltaic cell. The photovoltaic assembly has a positive conductor wire and a negative conductor wire extending therefrom. The positive conductor wire is electrically associated with a positive output cable at a positive output intersection and the negative conductor wire is electrically associated with a negative output cable at a negative output intersection. A by-pass diode is at a junction between the positive output intersection and the negative output intersection, selectively electrically joining the positive output cable with the negative output cable, thereby electrically by-passing the photovoltaic assembly. Encapsulating material completely surrounds the photovoltaic assembly and the by-pass diode within a single integral unit. The positive conductor wire, negative conductor wire and by-pass electrode are completely within the integral unit and the positive output cable and negative output cable extend from inside the integral unit to outside the integral unit.

In one further embodiment, the encapsulating material comprises a non-conductive material in the forms of layers above and below the photovoltaic cell assembly and the by-pass diode and in front of the by-pass diode, thereby completely encapsulating the photovoltaic assembly and by-pass diode in the integral unit. In one specific embodiment, the encapsulating material is a polymer, such as ethylene vinyl acetate polymer.

In an alternative further form, a sensor indicates that the photovoltaic assembly has failed. For example, the sensor, in one form, is a light which illuminates upon failure of the photovoltaic assembly.

The present invention, in another form thereof, relates to an array of photovoltaic modules. The photovoltaic modules include a photovoltaic assembly comprising at least one photovoltaic cell. The photovoltaic assembly has a positive conductor wire and a negative conductor wire extending therefrom. The positive conductor wire is electrically associated with a positive output electric cable at a positive output intersection and the negative conductor wire is electrically associated with a negative output cable at a negative output intersection. A by-pass diode is at a junction between the positive output intersection and the negative output intersection, selectively electrically joining the positive output cable with the negative output cable, thereby by-passing the photovoltaic assembly. Encapsulating material completely surrounds the photovoltaic assembly and the by-pass diode within a single integral unit. The positive conductor wire, negative conductor wire and by-pass diode are completely within the integral unit. The positive output cable and negative output cable extend from inside the integral unit to outside the integral unit. The at least two photovoltaic modules are electrically connected to each other, wherein, upon failure of one of the photovoltaic cell assemblies of the at least two photovoltaic modules, electrical current traverses the at least two photovoltaic modules by-passing through an operable one of the photovoltaic assemblies while by-passing a failed photovoltaic cell assembly.

The present invention, in another form thereof, relates to a photovoltaic module with integral junction. The photovoltaic module comprises a substrate, a first encapsulating material layer disposed on the substrate and a photovoltaic cell assembly comprising at least one photovoltaic cell. The photovoltaic cell assembly is disposed on the first encapsulating material. The photovoltaic assembly has a positive conductor wire and a negative conductor wire extending therefrom. The positive conductor wire is electrically associated with a positive output electric cable at a positive output intersection and the negative conductor wire is electrically associated with a negative output cable at a negative output intersection. A by-pass diode is disposed on the first encapsulating material layer and extends in a plane of the photovoltaic cell assembly. The by-pass diode is at a junction between the positive output intersection and the negative output intersection, selectively electrically joining the positive output cable with the negative output cable, thereby by-passing the photovoltaic assembly. The by-pass diode is completely encapsulated via encapsulating material. A second encapsulating material layer is disposed on the photovoltaic cell assembly and the by-pass diode. A transparent superstrate is on the second encapsulating material layer.

### BRIEF DESCRIPTION OF THE DRAWINGS

For a better understanding of the present invention, and to show how the same may be carried into effect, reference will now be made, by way of example only, to the accompanying drawings and tables in which:

FIG. 1 is a plan view of a photovoltaic module with integral junction, in accordance with the present invention;

FIG. 2 is a sectional view of the photovoltaic module taken along line 2-2 in FIG. 1;

FIG. 3 is an exploded view of the photovoltaic module of FIG. 1;

FIG. 4 is a partial sectional view of the photovoltaic module taken along line 4-4 of FIG. 1;

FIG. 5 is a sectional view of an array of photovoltaic modules, in accordance with another aspect of the present invention; and

FIG. 6 is a schematic of a prior art photovoltaic module and junction box.

### DETAILED DESCRIPTION OF THE INVENTION

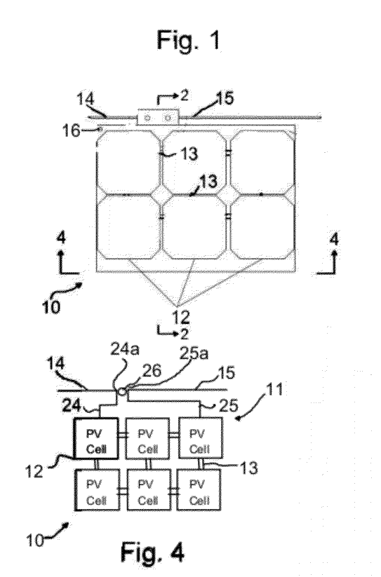

The present photovoltaic module with integral junction will now be described with reference to the drawings and, in particular, FIGS. 1-4. Photovoltaic module 10 has a photovoltaic assembly 11 formed from a plurality of photovoltaic cells 12. Each of the photovoltaic cells 12 are electrically connected to one another via wires 13. Negative output cable 14 and positive output cable 15 extend from the photovoltaic module 10. An indicator sensor, such as indicator 16, illuminates to indicate a failure in the photovoltaic assembly 11. For example, a failure of one or more of the photovoltaic cells 12 in the photovoltaic assembly 11 results in indicator light 16 illuminating.

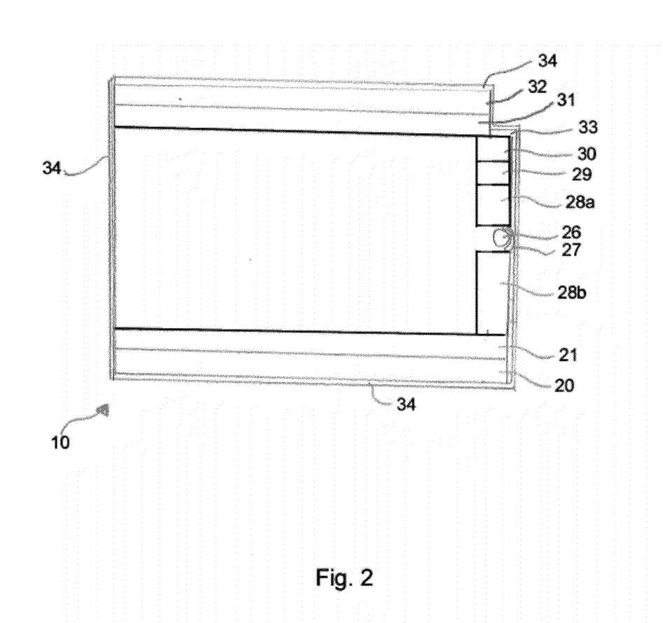

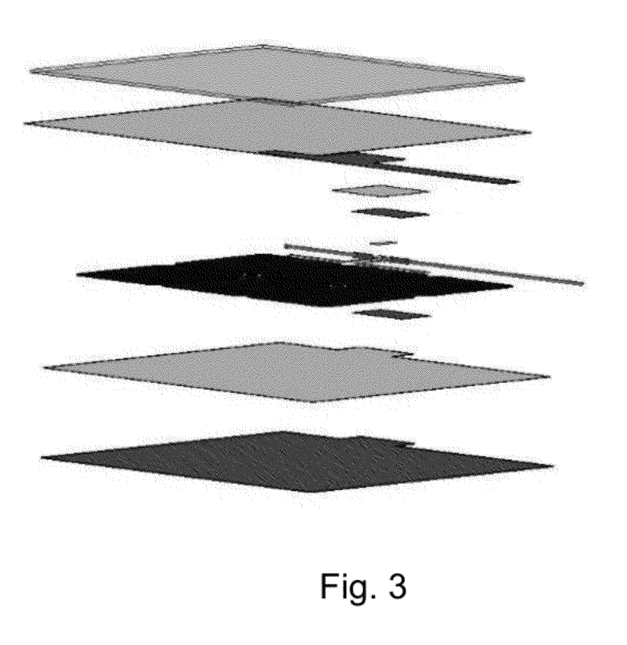

Referring now specifically to FIGS. 2 and 3, along with FIG. 4, the photovoltaic module 10 comprises a series of layers which form a single integral unit. The photovoltaic module 10 has a backsheet or substrate 20 and a first encapsulating material, for example a polymer, such as ethylene vinyl acetate copolymer (EVA), first EVA layer 21. The photovoltaic assembly 11 is disposed on the first EVA layer 21. Negative conductor wire 24 and positive conductor wire 25 extend from the plane of the photovoltaic assembly 11. The negative conductor wire 24 is electrically connected to the negative output cable 14 and the positive output cable 15 at the respective intersection, 24a, 25a (FIG. 4).

A by-pass diode 26 is connected to the negative output cable 14 and the positive output cable at intersections 24a, 25a respectively. A strip of EVA tape 27 is wrapped around the outside of the by-pass diode 26. A photovoltaic encapsulated sheet, e.g., an ionomer-based material, such as DUPONT PV5316, form top 28a and bottom 28b, above and below the EVA tape 27 covering by-pass diode 26. EVA patch 29 is disposed over top 28a and diode cover 30 is placed over the EVA patch 29. A second EVA material layer 31 completely covers the photovoltaic assembly 11 and part of the diode cover 30. Finally, glass superstrate 32 is on top of the second EVA material layer 31. A strip of tape, such as acrylic tape 33, is displaced on the peripheral edge of the photovoltaic module 10, including a portion of the second EVA layer 31, diode cover 30, EVA patch 29, top 28a, EVA tape 27, bottom 28b, first EVA layer 21 and backsheet 20.

It will now be apparent to one skilled in the art that the photovoltaic assembly 11 and the by-pass diode 26 of the present photovoltaic module are completely encapsulated in a single integral unit. For example, the internal unit of photovoltaic module 10 is defined by the EVA layers 21 and 31 over the photovoltaic assembly 11 and on diode cover 30, EVA patch 29, top 28a, bottom 28b and EVA tape 29.

### Example of One Preferred Manufacturing Method

In a non-limiting, advantageous manufacturing method, the photovoltaic module 10 is manufactured by first laying out one or more of the photovoltaic cells 12 on a work surface. The negative conductor wire 24 and positive conductor wire 25 are soldered to the negative output cable 14 and the positive output cable 15 at intersections 24a, 25a, respectively. Next, the by-pass, diode 26 is soldered to the intersections 24a, 25a. The EVA tape 27 is wrapped around the exterior surface of the by-pass diode 26 and the top 28a and bottom 28b are placed above and below the by-pass diode 26. Heat is applied to melt the material of the EVA tape 27. Next, EVA patch 29 is placed over the upper diode cover 28a, followed by diode cover 30.

The peripheral strip of tape 33 is applied to the perimeter of the photovoltaic module 10, along the perimeter adjacent the bypass diode 26. The photovoltaic assembly 11 with covered by-pass diode 26 is transferred from the work surface to the backsheet 20, covered with the first EVA layer 21. Subsequently, the diode cover 30 is positioned and the second EVA layer 31 is placed over the photovoltaic assembly 11, followed by the glass or film superstrate 32.

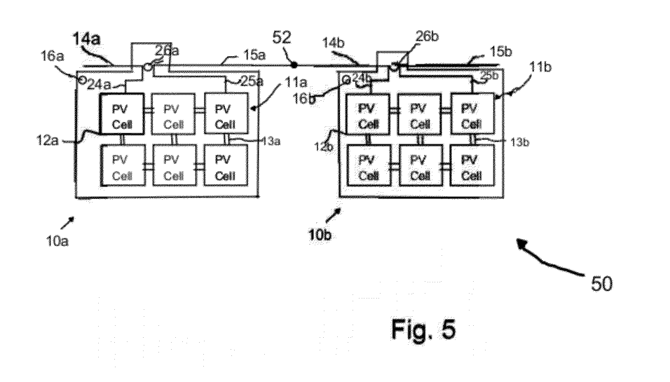

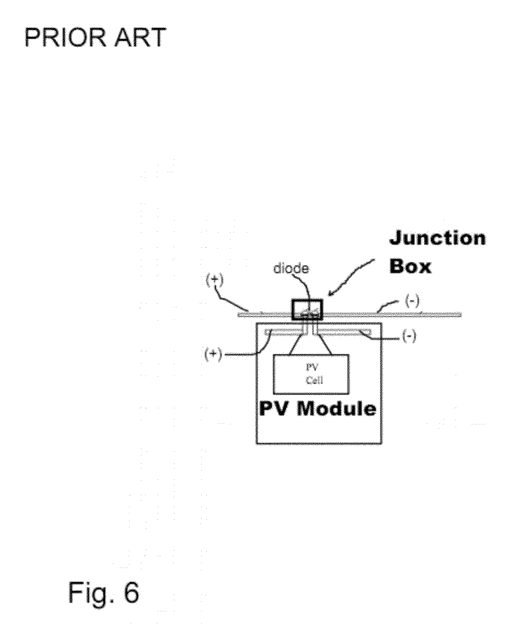

Referring now to FIG. 5, photovoltaic array 50 comprises a plurality of photovoltaic modules, depicted as two modules to simplify the drawing. Photovoltaic module 10a is electrically joined to photovoltaic module 10b at connection 52. Although FIG. 5 depicts just two photovoltaic modules 11a and 11b, the array may contain hundreds of modules connected together.

During operation of the photovoltaic module 10a, 10b, electrical current flows from negative output electric cable 14a to negative conductor wire 24a, through the photovoltaic assembly 11a to the positive conductor wire 25a to the positive output cable 15a, and then on to the photovoltaic module 10b. Upon failure of one of the modules, for example, photovoltaic assembly 11a, the by-pass diode 26a selectively electrically joins the positive output cable 14a with the negative output cable 15a, thereby electrically by-passing the photovoltaic assembly 11a. As a result, current passes through the photovoltaic module 10a, by-passing the photovoltaic assembly 11a and continues on to the photovoltaic module 10b.

It will now be apparent to one of ordinary skill in the art that the present photovoltaic module with integral junction provides features and advantages over prior photovoltaic modules. Integrating the by-pass diode 26 within the module avoids having to use an external junction box which then requires sealing and necessarily involves additional thickness or bulk. In addition, the series of layers of encapsulate, substrate, superstrate, and exterior laminate results in a single integral unit in which the photovoltaic assembly and by-pass diode are encapsulated within a single integral unit. As a result of the present integral junction, the height of the module with junction is substantially less than prior modules with junction boxes, allowing the present photovoltaic module to have a low profile relative to the plane of a solar module, allowing flush and nearly flush installation.

Although the invention has been described in considerable detail with respect to preferred embodiments, it will be apparent that the invention is capable of numerous modifications and variations, apparent to those skilled in the art, without departing from the spirit and scope of the invention.

What is claimed is:

1. A photovoltaic module with integral junction, comprising:
a photovoltaic cell assembly comprising at least one photovoltaic cell, the photovoltaic assembly having a positive conductor wire and a negative conductor wire extending therefrom, the positive conductor wire electrically associated with a positive output electric cable at a positive output intersection and the negative conductor wire electrically associated with a negative output cable at a negative output intersection;
a by-pass diode at a junction between the positive output intersection and the negative output intersection, selectively electrically joining the positive output cable with the negative output cable, thereby by-passing the photovoltaic cell assembly; and
encapsulating material completely surrounding the photovoltaic cell assembly and the by-pass diode within a single integral unit, with the positive conductor wire, the negative conductor wire and the by-pass diode being completely within the integral unit and the positive output cable and negative output cable extending from inside the integral unit to outside the integral unit.

2. The photovoltaic module of claim 1, wherein the encapsulating material comprises a non-conducting material in the form of layers above and below the photovoltaic cell assembly and by-pass diode and in front of the by-pass diode, thereby completely encapsulating the photovoltaic cell assembly and by-pass diode in the integral unit.

3. The photovoltaic module of claim 2, wherein the encapsulating material above the photovoltaic cell assembly is transparent.

4. The photovoltaic module of claim 1, further comprising a glass or film layer over the photovoltaic cell assembly.

5. The photovoltaic module of claim 1, further comprising a sensor for indicating the photovoltaic cell assembly has failed.

6. The photovoltaic module of claim 5, wherein the sensor is a light which illuminates upon failure of the photovoltaic cell assembly.

7. The photovoltaic module of claim 1, wherein the photovoltaic cell assembly comprises at least two photovoltaic cells electrically connected to each other.

8. An array of photovoltaic modules, comprising:
at least two photovoltaic modules, each module comprising:
a photovoltaic cell assembly comprising at least the photovoltaic cell, the photovoltaic assembly having a positive conductor wire and a negative conductor wire extending therefrom, the positive conductor wire electrically associated with a positive output electric cable at a positive output intersection and the negative conductor wire electrically associated with a negative output cable at a negative output intersection;
a by-pass diode at a junction between the positive output intersection and the negative output intersection, selectively electrically joining the positive output cable with the negative output cable, thereby by-passing the photovoltaic cell assembly; and
encapsulating material completely surrounding the photovoltaic cell assemblies and the by-pass diode within a single integral unit, with the positive conductor wire, the negative conductor wire and the by-pass diode being completely within the integral unit and the positive output cable and negative output cable extending from inside the integral unit to outside the integral unit,
the at least two photovoltaic modules being electrically connected to each other,
wherein, upon failure of one of the at least two photovoltaic cell assemblies of the at least two photovoltaic modules, electrical current will traverse the at least two photovoltaic modules by passing through an operable one of the photovoltaic cell assemblies while by-passing a failed photovoltaic cell assembly.

9. The array of photovoltaic modules of claim 8, wherein the encapsulating material above the photovoltaic cell assembly is transparent.

10. The array of photovoltaic modules of claim 8, further comprising a glass or film layer over the photovoltaic cell assembly.

11. The array of photovoltaic modules of claim 8, further comprising a sensor for indicating the photovoltaic cell assembly has failed.

12. The array of photovoltaic modules of claim 11, wherein the sensor is a light which illuminates upon failure of the photovoltaic cell assembly.

13. The array of photovoltaic modules of claim 8, wherein the photovoltaic cell assembly comprises at least two photovoltaic cells electrically connected to each other.

14. A photovoltaic module with integral junction, comprising:
a substrate;
a first encapsulating material layer disposed on the substrate;
a photovoltaic cell assembly comprising at least one photovoltaic cell, the photovoltaic cell assembly disposed on the first encapsulating material layer, the photovoltaic cell assembly having a positive conductor wire and a negative conductor wire extending therefrom, the positive conductor wire electrically associated with a positive output electric cable at a positive output intersection and the negative conductor wire electrically associated with a negative output cable at a negative output intersection;
a by-pass diode disposed on the first encapsulating material layer and extending in a plane of the photovoltaic cell assembly, the by-pass diode at a junction between the positive output intersection and the negative output intersection, selectively electrically joining the positive output cable with the negative output cable, thereby by-passing the photovoltaic cell assembly, said by-pass diode being completely encapsulated via encapsulating material;
a second encapsulating material layer disposed on the photovoltaic cell assembly and the by-pass diode; and
a transparent superstrate on the second encapsulating material layer.

15. The photovoltaic module with integral junction of claim 14, wherein the photovoltaic cell assembly and the by-pass diode form a single integral unit, with the positive conductor wire, the negative conductor wire and the by-pass diode being completely within the integral unit and the positive output cable and negative output cable extending from inside the integral unit to outside the integral unit.

16. The photovoltaic module of claim 14, further comprising a sensor for indicating the photovoltaic cell has failed.

17. The photovoltaic module of claim 14, wherein the photovoltaic cell assembly comprises at least two photovoltaic cells electrically connected to each other.
